(19) United States
(12) Patent Application Publication
(10) Pub. No.: US 2007/0072410 A1
(43) Pub. Date: Mar. 29, 2007

(54) Method of forming copper interconnection using dual damascene process

(75) Inventor: Eun Jong Shin, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/527,980

(22) Filed: Sep. 26, 2006

(30) Foreign Application Priority Data
Sep. 28, 2005 (KR) 10-2005-0090343

(51) Int. Cl. H01L 21/4763

(52) U.S. Cl. 438/622

(57) ABSTRACT

Disclosed is a method of forming a copper interconnection using a dual damascene process. The method generally prevents formation of an undeveloped photoresist caused by the topology between a via hole and a trench and reduces or prevents defects in the copper interconnection, such as disconnection, via holes or voids. A buffer layer is formed on a protective layer in the via hole before the trench is formed. The buffer layer includes a material having higher etch selectivity with respect to the interlayer dielectric layer. In one implementation, the buffer layer includes silicon nitride. The buffer layer is obtained by depositing a buffer material and then polishing the buffer material by chemical mechanical polishing. The buffer layer is removed when the trench is formed.

This application claims the benefit of Korean Application No. 10-2005-0090343, filed on Sep. 28, 2005, which is incorporated by reference herein in its entirety.

### BACKGROUND OF THE INVENTION

1. Field of the Invention

The present invention relates to a metal interconnection technology for a semiconductor device. More specifically, the present invention relates to a method of forming a copper interconnection using a dual damascene process.

2. Background of the Related Art

As interest in the ultra deep sub-micron CMOS devices having sizes of 90 nm or less has grown, studies for using low-k dielectrics in copper interconnection processes have been actively performed. One of the major challenges to be solved in the copper interconnection technology using a low-k dielectric is an integration issue. That is, reliability of the semiconductor device, such as electro-migration (EM), stress-migration (SM), or time dependent dielectric breakdown (TDDB) which may occur due to the characteristics of the low-k material, has become a serious problem in the copper interconnection technology. In addition, as the dual damascene technology is applied to the copper interconnection process, various defects such as openings, a poor surface for contact at the bottom of via holes, or voids in the copper interconnection, are presented. These defects may exert a bad influence upon the productivity and reliability of the semiconductor devices.

FIGS. 1a to 1d show a conventional technology for forming a copper interconnection using a low-k dielectric and a dual damascene process.

Referring to FIG. 1a, a capping layer 11 and an interlayer dielectric layer 12 are sequentially deposited on top surface of a lower copper interconnection 10. The capping layer 11 may be formed by silicon nitride (SiN) or silicon carbon nitride (SiCN), and the interlayer dielectric layer 12 may include a stacked structure of undoped silicate glass (USG) formed from plasma-assisted deposition of silicon dioxide from monosilane (plasma silane, or p-SiH₄), fluorine-doped silicon glass (FSG) and plasma silane (p-SiH₄).

Referring to FIG. 1b, via holes and a trench are formed through a conventional dual damascene process. First, a photoresist pattern (not shown) used for forming the via holes is coated on the interlayer dielectric layer 12, and then a dry etching process is performed to form the via holes 13. Then, the photoresist pattern is removed. After that, an etch back process is performed after filling the via holes 13 with a novolac resin or a bottom anti-reflective coating (BARC), which may be a kind of photoresist, thereby forming a protective layer 14.

Then, a second photoresist is coated in the interlayer dielectric layer 12 having the via holes 13 therein partially filled with the protective layer 14, and photolithographic exposure and development processes are carried out on the second photoresist, thereby forming a photoresist pattern 15 to form the trench. At this time, a part 15a of the photoresist may not be completely developed due to the topology of an overlap area between the via holes and the trench.

As shown in FIG. 1c, such an undeveloped photoresist 15a creates a non-trench region 17 after the dry etching process to form the trench 16 has been completed. This type of defect in the trench pattern may cause defects of the copper interconnection in the following processes such as disconnections, poor contact surface at the bottom of via holes (e.g. resulting from a high aspect ratio of the via hole in region 17), or voids in the copper interconnection. FIG. 2 is a plan view showing via holes 14 and the trench 16 of the conventional copper interconnection having one or more of the above defects (see reference numeral 17).

After the trench etching process has been completed, as shown in FIG. 1c, the protective layers 14 (see FIG. 1b) are removed from the via holes 13 and the capping layer 11 remaining on the bottom of the via holes 13 is removed by dry etching.

Then, after depositing a diffusion barrier and a copper seed layer, copper is deposited through an electrochemical plating (ECP) process. After that, a chemical mechanical polishing (CMP) process is performed with respect to a resultant structure, thereby providing a copper interconnection 18 having the dual damascene structure as shown in FIG. 1d.

### SUMMARY OF THE INVENTION

It is, therefore, an object of the present invention is to provide a method of forming a copper interconnection using a dual damascene process, capable of reducing the incidence of or preventing photoresist poisoning and/or other cause(s) of undeveloped photoresist, which may be derived from the topology between via holes and a trench.

Another object of the present invention is to provide a method of forming a copper interconnection using a dual damascene process, capable of preventing defects of the copper interconnection, such as disconnection, poor contact surface at the bottom of via holes or voids in the copper interconnection, caused by the photoresist poisoning.

Still another object of the present invention is to provide a method of forming a copper interconnection using a low-k dielectric and a dual damascene process to improve the productivity and reliability of semiconductor devices.

According to an aspect of the present invention, there is provided a method of forming a copper interconnection, in which a buffer layer is formed on the protective layer in a via hole before a trench is formed in order to prevent or reduce the occurrence of an undeveloped photoresist when a photoresist pattern is formed to provide the trench.

According to another aspect of the present invention, the method comprises the steps of: sequentially depositing a capping layer and a dielectric layer on a predetermined lower structure; forming a via hole in the dielectric layer; forming a protective layer in the via hole; forming a buffer layer on the protective layer in the via hole; forming a trench in an upper portion of the dielectric layer overlapping the via hole; removing the protective layer and the capping layer exposed at the bottom of the via hole; and depositing copper such that the via hole and the trench are filled with copper, and chemical mechanical polishing a resultant structure, thereby obtaining the copper interconnection.

Preferably, the buffer layer includes silicon nitride (SiN) having high etch selectivity with respect to the dielectric layer (e.g., when the dielectric layer comprises a silicon oxide). After depositing a buffer material, the buffer material deposited on the dielectric layer is removed by chemical mechanical polishing. The buffer layer is simultaneously removed (e.g., in the same processing step) when the trench is formed.

The interlayer dielectric layer and the buffer layer may be etched in the same etching ratio when the trench is formed. The capping layer may comprise silicon nitride (SiN) or silicon carbon nitride (SiCN). The dielectric layer may comprise fluorine-doped silicon glass (FSG) or carbon-doped silicon oxide (SiOC). The protective layer may comprise a novolac resin or a bottom anti-reflective coating (BARC).

### BRIEF DESCRIPTION OF DRAWINGS

FIGS. 1a to 1d are sectional views illustrating a conventional method of forming a copper interconnection;

FIG. 2 is a plan view illustrating a defect in a conventional copper interconnection; and

FIGS. 3a to 3c are sectional views illustrating a method of forming a copper interconnection according to the preferred embodiment of the present invention.

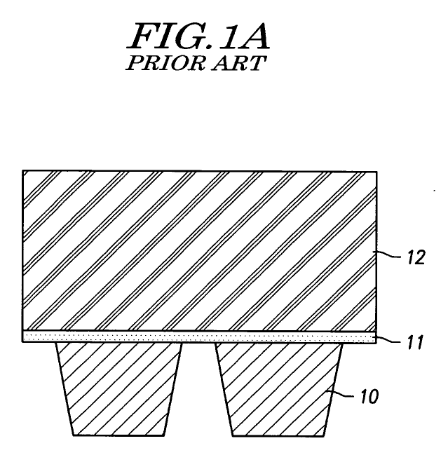

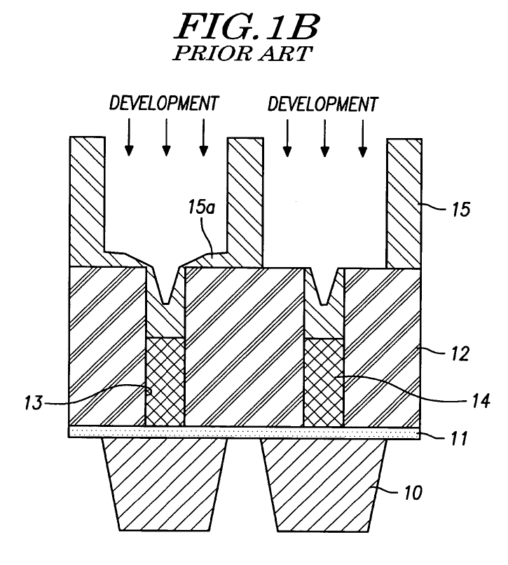

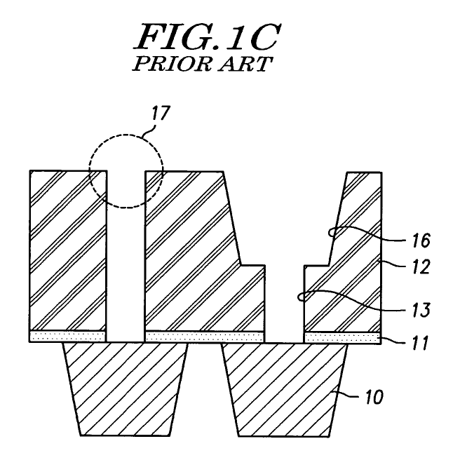

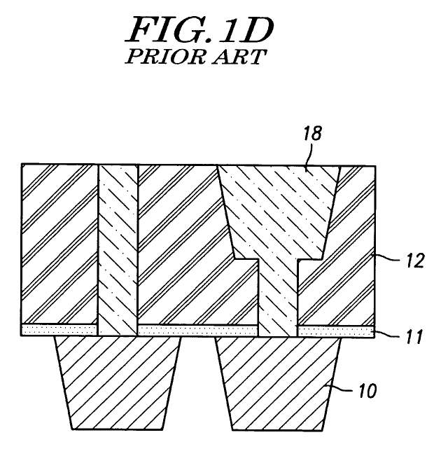

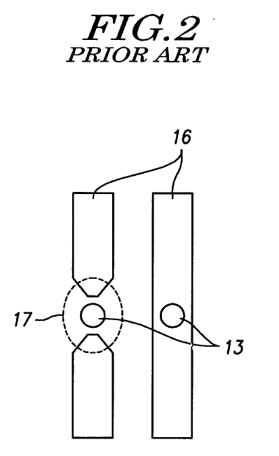

### DETAILED DESCRIPTION OF THE INVENTION

Hereinafter, preferred embodiments according to the present invention will be described in detail, with reference to the following drawings.

It should be noted that the embodiments described below do not intend to limit the scope of the present invention, but assist those skilled in the art to clearly understand the present invention. In the following description of the present invention, some structures or manufacturing processes are omitted for simplicity and clarity of the description. Further, some of elements are exaggerated, omitted or simplified in the drawings and the elements may have sizes different from those shown in the drawings, in practice.

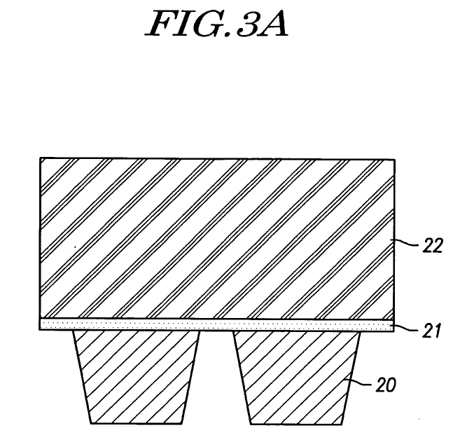

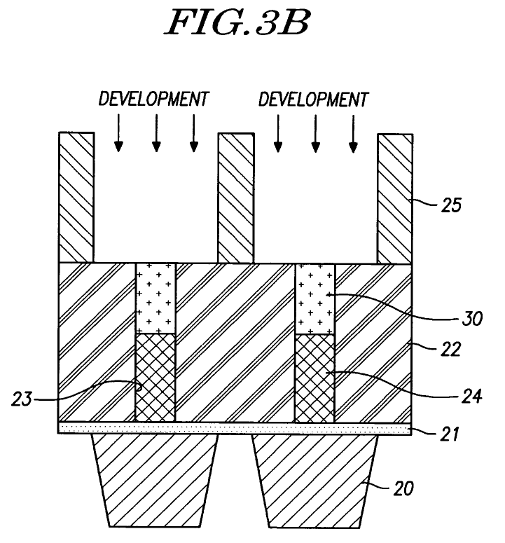

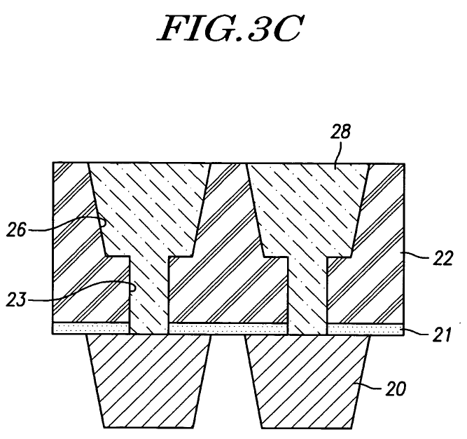

FIGS. 3a to 3c are sectional views illustrating a method of forming a copper interconnection according to the preferred embodiment of the present invention.

Referring to FIG. 3a, similar to the conventional copper interconnection technology, a capping layer 21 and a dielectric layer 22 are sequentially deposited on the top surface of a lower copper interconnection 20. The dielectric layer 22 is, in effect, between metal layers, as so it is sometimes referred to as an interlayer dielectric layer. The capping layer 21 is deposited first in order to prevent copper diffusion into the overlying first interlayer dielectric layer 22 and/or to prevent oxygen diffusion into the lower copper interconnection 20. The capping layer 21 may comprise or consist essentially of silicon nitride (SiN) or silicon carbon nitride (SiCN). In addition, the dielectric layer 22 includes a low-k material, such as fluorine-doped silicon glass (FSG) or carbon-doped silicon oxide (SiOC). Preferably, the interlayer dielectric layer 22 has a stacked structure produced by forming a plasma silane (p-SiH₄) film on top and bottom portions of the bulk interlayer dielectric layer 22.

Referring to FIG. 3b, via holes and trenches are sequentially formed through a conventional dual damascene process. First, a photoresist pattern (not shown) is coated to form the via holes, and then a dry etching process is performed using the photoresist pattern as a mask, thereby forming the via holes 23 in the dielectric layer 22. Then, the photoresist pattern is removed. After that, the via holes 23 are filled with a novolac resin or a bottom anti-reflective coating (BARC), which is a kind of photoresist, then an etch back process is performed, thereby forming a protective layer 24. In the embodiment shown, the protective layer does not completely fill the via hole 23.

Next, a predetermined buffer material is deposited before the trench is formed, and then the buffer material deposited on the interlayer dielectric layer 22 outside the via hole 23 is removed by chemical mechanical polishing, thereby forming a buffer layer 30 on the protective layer 24 formed in the via hole 23. When a photoresist pattern 25 is formed to provide the trench after the buffer layer 30 has been formed, the buffer layer 30 can prevent undeveloped photoresist from remaining in the via hole or at the bottom of the opening in the photoresist pattern 25 that may result from the topology between the via holes and the trench.

Preferably, the buffer layer 30 includes a material capable of preventing a depth variation of the trench and a thickness variation of the dielectric layer that may be caused by the chemical mechanical polishing process. In this regard, the buffer layer 30 preferably includes material having superior selectivity (e.g., a relatively low etch rate) with respect to the dielectric layer 22 (that is, relative to the etch rate the dielectric layer 22). In one embodiment, the buffer layer 30 comprises silicon nitride (SiN), which generally has high etch selectivity with respect to oxide under predetermined conditions for etching many known silicon oxides. An etch selectivity of 10:1, 20:1, 50:1 or more may be suitable.

Then, as shown in FIG. 3c, a dry etching process is performed using the photoresist pattern 25 as a mask to form the trench 26 at the upper portion of the via hole 23. At this time, the buffer layer 30 remaining in the via hole 23 may be simultaneously removed. Accordingly, it is preferable to etch the dielectric layer 22 and the buffer layer 30 at the same etching ratio or rate in the trench etching process (i.e., by nonselective etching). Preferably, the dielectric layer 22 and the buffer layer 30 have an etching selectivity of about 1:1 during the trench etching process. Alternatively, the dielectric layer 22 and the buffer layer 30 may be sequentially etched if the etching selectivity is not about 1:1, but even in such sequential etching, the etching selectivity is preferably low (e.g., about 5:1, 3:1, 2:1 or less). In such sequential etching, after the trench is etched to a predetermined depth (e.g., by etching for a predetermined period of time), the remaining buffer layer 30 is selectively etched relative to the dielectric layer 22.

After that, similar to the conventional copper interconnection technology, the protective layer 24 (see FIG. 3b) in the via hole 23 is removed, and the capping layer 21 remaining on and/or exposed in the bottom of the via hole 23 is removed through a dry etching process. In addition, although it is not illustrated in figures, a diffusion barrier and a copper seed layer are deposited, and then copper is deposited by electrochemical plating (ECP) sufficiently to fill the via holes 23 and the trench 26. After that, a chemical mechanical polishing (CMP) process is performed on the resultant structure, thereby providing a copper interconnection 28 having a dual damascene structure as shown in FIG. 3c. The diffusion barrier, for instance, may include tantalum-based metals or titanium-based metals (e.g., TiN or TaN, which may have an adhesive layer such as Ti or Ta thereunder), and is subject to a heat-treatment process before or after the CMP process.

As described above, according to the method of forming the copper interconnection of the present invention, the buffer layer is formed on a protective layer in the via hole, before the photolithography process is performed to form the trench. Thus, photoresist poisoning and/or other causes of undeveloped photoresist in the trench area due to a topology between the via hole and the trench can be reduced or prevented when the photoresist is developed to form the trench.

Therefore, the present invention can reduce or prevent defects in the copper interconnection, such as disconnection, poor contact surface in the via holes, and voids in the copper interconnection, generally resulting in improvements in the productivity and reliability of the semiconductor devices when forming copper interconnections or metallization using a low-k dielectric layer and a dual damascene process.

While the invention has been shown and described with reference to certain preferred embodiments thereof, it will be understood by those skilled in the art that various changes and modifications in form and details may be made therein without departing from the spirit and scope of the invention as defined in the appended claims.

What is claimed is:

1. A method of forming a copper interconnection, the method comprising the steps of:
sequentially depositing a capping layer and a dielectric layer on a lower structure;
forming a via hole in the dielectric layer;
forming a protective layer in the via hole;
forming a buffer layer on the protective layer in the via hole;
forming a trench in an upper portion of the dielectric layer overlapping the via hole;
removing the protective layer and the capping layer exposed at the bottom of the via hole; and
depositing copper such that the via hole and the trench are filled with copper, and chemical mechanical polishing a resultant structure, thereby obtaining the copper interconnection.

2. The method of claim 1, wherein the buffer layer includes silicon nitride (SiN).

3. The method of claim 1, wherein the step of forming the buffer layer includes depositing the buffer material, and removing the buffer material on the dielectric layer by chemical mechanical polishing.

4. The method of claim 1, wherein the buffer layer is simultaneously removed when the trench is formed.

5. The method of claim 1, wherein the dielectric layer and the buffer layer are etched in a same etching ratio when the trench is formed.

6. The method of claim 1, wherein the capping layer includes silicon nitride (SiN) or silicon carbon nitride (SiCN).

7. The method of claim 1, wherein the dielectric layer includes fluorine-doped silicon glass (FSG) or carbon-doped silicon oxide (SiOC).

8. The method of claim 1, wherein the protective layer includes a novolac resin or a bottom anti-reflective coating (BARC).

9. The method of claim 1, wherein the protective layer doe not completely fill the via hole.

10. The method of claim 9, wherein the buffer layer fills the remainder of the via hole.

11. A method of forming a copper interconnection, the method comprising the steps of:
forming a buffer layer on a protective layer in a via hole in a dielectric layer;
forming a trench in an upper portion of the dielectric layer overlapping the via hole by simultaneously removing the upper portion of the dielectric layer and the buffer layer;
removing the protective layer to expose the capping layer in the via hole;
removing the exposed capping layer;
filling the via hole and the trench with copper; and
polishing a resultant structure, thereby obtaining the copper interconnection.

12. The method of claim 11, wherein the buffer layer comprises silicon nitride (SiN).

13. The method of claim 11, wherein the dielectric layer comprises a silicon oxide.

14. The method of claim 13, wherein the dielectric layer comprises fluorine-doped silicon glass (FSG) or carbon-doped silicon oxide (SiOC).

15. The method of claim 11, wherein the dielectric layer comprises fluorine-doped silicon glass (FSG) or carbon-doped silicon oxide (SiOC).

16. The method of claim 15, wherein the dielectric layer further comprises a first plasma silane layer under the fluorine-doped silicon glass (FSG) or carbon-doped silicon oxide (SiOC), and a second plasma silane layer over the FSG or SiOC.

17. The method of claim 11, wherein the protective layer doe not completely fill the via hole, the step of forming the buffer layer includes depositing the buffer material in a remainder of the via hole, and removing the buffer material on the dielectric layer by chemical mechanical polishing.

18. The method of claim 11, wherein the dielectric layer and the buffer layer are etched at a same etching rate when the trench is formed.

19. The method of claim 11, wherein the capping layer comprises silicon nitride (SiN) or silicon carbon nitride (SiCN).

20. The method of claim 11, wherein the protective layer comprises a novolac resin or a bottom anti-reflective coating (BARC).
